(19) United States
(12) Patent Application Publication
(10) Pub. No.: US 2026/0191077 A1
(43) Pub. Date: Jul. 2, 2026

(54) FILM-SHAPED ADHESIVE FOR SEMICONDUCTORS, METHOD FOR PRODUCING FILM-SHAPED ADHESIVE FOR SEMICONDUCTORS, ADHESIVE TAPE, METHOD FOR PRODUCING SEMICONDUCTOR DEVICE, AND SEMICONDUCTOR DEVICE

(71) Applicant: Resonac Corporation, Minato-ku, Tokyo (JP)

(72) Inventors: Hiroyuki ISHIGE, Minato-ku, Tokyo (JP); Ryosuke KIMURA, Minato-ku, Tokyo (JP); Makoto SATO, Minato-ku, Tokyo (JP); Shogo SOBUE, Minato-ku, Tokyo (JP)

(21) Appl. No.: 18/856,057

(22) PCT Filed: Feb. 28, 2024
(86) PCT No.: PCT/JP2024/007416

§ 371 Date: Oct. 11, 2024

(30) Foreign Application Priority Data
Apr. 24, 2023 (JP) 2023-070817

(51) Int. Cl. H10W 72/30; H10W 72/00; H10W 90/00

(52) U.S. Cl. CPC H10W 72/354; H10W 72/07338; H10W 72/322; H10W 90/732; H10W 90/734; H10W 72/856; H10W 90/722; H10W 90/724

(57) ABSTRACT

A film-shaped adhesive for semiconductors having: a first adhesive region that does not include a flux compound; and a second adhesive region including a flux compound, along the thickness direction, in which the first adhesive region includes a first epoxy resin, a first imidazole-based curing agent, and a (meth)acrylic compound, and the second adhesive region includes a second epoxy resin, a second imidazole-based curing agent, and a flux compound.

### TECHNICAL FIELD

The present disclosure relates to a film-shaped adhesive for semiconductors, a method for producing a film-shaped adhesive for semiconductors, an adhesive tape, a method for producing a semiconductor device, and a semiconductor device.

### BACKGROUND ART

Wire bonding systems using fine metal wires such as gold wires have been widely applied to connect semiconductor chips and substrates. Meanwhile, in order to cope with requests for higher functionalization, higher integration, speed improvement, and the like for semiconductor devices, a flip-chip connection system (FC connection system) in which a semiconductor chip and a substrate are directly connected by forming conductive protrusions called bumps on the semiconductor chip or the substrate, is becoming widespread.

For example, with regard to the connection between a semiconductor chip and a substrate, a COB (Chip On Board) type connection system that is actively used in BGA (Ball Grid Array), CSP (Chip Size Package), and the like, also corresponds to the FC connection system. Furthermore, the FC connection system is also widely used in a COC (Chip On Chip) type connection system in which semiconductor chips are connected to each other by forming connecting parts (for example, bumps and wiring lines) on the semiconductor chips.

In packages where further size reduction, thickness reduction, and higher functionalization are strongly required, chip stack type packages, POP (Package On Package), TSV (Through-Silicon Via), and the like, in which chips are stacked into multi-stages by using the above-mentioned connection systems, are also beginning to become widespread. Since such a technology of stacking into multi-stages allows three-dimensional arrangement of connecting members such as semiconductor chips, packages can be made smaller as compared to techniques of arranging the connecting members two-dimensionally. Furthermore, since the technology of stacking into multi-stages is also effective in terms of improvement of semiconductor performance, noise reduction, reduction of mounting area, electric power saving, and the like, attention has been paid to the technology as a next-generation semiconductor wiring technology.

However, for the connection between connecting parts, metal bonding is generally used from the viewpoint of sufficiently ensuring connection reliability (for example, insulation reliability). Examples of the metal mainly used for the above-described connecting parts (for example, bumps and wiring lines) include solder, tin, gold, silver, copper, and nickel, and conductive materials including a plurality of kinds of these are also used. With regard to the metal used in the connecting parts, since the surface is oxidized to generate an oxide film, and impurities such as oxides adhere to the surface, impurities may occur on the connecting surfaces of the connecting parts. When such impurities remain, there is concern that the connection reliability (for example, insulation reliability) between a semiconductor chip and a substrate or between two semiconductor chips may deteriorate, and the benefits of adopting the above-mentioned connection system may be lost.

Furthermore, as a method of suppressing the generation of these impurities, there is a method of coating connecting parts with an antioxidant film, which is known as an OSP (Organic Solderbility Preservatives) treatment or the like; however, this antioxidant film may cause deterioration of solder wettability, deterioration of connectivity, and the like during a connection process.

Thus, as a method for removing the above-mentioned oxide film and impurities, a method of using a single-layered film containing a flux agent on a semiconductor material (see, for example, Patent Literature 1), a method of using a two-layered film composed of a thermosetting resin layer and a thermoplastic resin layer containing an acid component, and the like have been proposed (see, for example, Patent Literature 2).

### CITATION LIST

### Patent Literature

Patent Literature 1: International Publication WO 2013/125086
Patent Literature 2: International Publication WO 2016/117350

### SUMMARY OF INVENTION

### Technical Problem

An object of an aspect of the present disclosure is to provide a film-shaped adhesive for semiconductors that can suppress the amount of fillet generated while ensuring sufficient sealing properties.

### Solution to Problem

The present disclosure provides the following items [1] to [15].
[1] A film-shaped adhesive for semiconductors, comprising, along a thickness direction:
a first adhesive region not including a flux compound; and
a second adhesive region including a flux compound, wherein the first adhesive region includes a first epoxy resin, a first imidazole-based curing agent, and a (meth)acrylic compound, and
the second adhesive region includes a second epoxy resin, a second imidazole-based curing agent, and the flux compound.
[2] The film-shaped adhesive for semiconductors according to [1], wherein the first adhesive region does not include a radical polymerization initiator.
[3] The film-shaped adhesive for semiconductors according to [1] or [2], wherein at least one of the first epoxy resin and the second epoxy resin includes an epoxy resin that is liquid at 25° C.
[4] The film-shaped adhesive for semiconductors according to any one of [1] to [3], wherein at least one of the first epoxy resin and the second epoxy resin includes a triphenolmethane type epoxy resin.
[5] The film-shaped adhesive for semiconductors according to any one of [1] to [4], wherein at least one of the first imidazole-based curing agent and the second imidazole-based curing agent includes a triazine ring.
[6] The film-shaped adhesive for semiconductors according to any one of [1] to [5], wherein a ratio of a content of the first epoxy resin with respect to a content of the (meth)acrylic compound in the first adhesive region is 3 to 11 in terms of mass ratio.
[7] The film-shaped adhesive for semiconductors according to any one of [1] to [6], wherein the (meth)acrylic compound includes a polyfunctional (meth)acrylic compound having two to eight (meth)acryloyl groups.
[8] The film-shaped adhesive for semiconductors according to any one of [1] to [7], wherein the flux compound includes a polycarboxylic acid.
[9] The film-shaped adhesive for semiconductors according to any one of [1] to [8], wherein a thickness of the first adhesive region is 1 to 50 μm, and a thickness of the second adhesive region is 0.5 to 2 times the thickness of the first adhesive region.
[10] The film-shaped adhesive for semiconductors according to any one of [1] to [9], wherein the film-shaped adhesive for semiconductors is electrically non-conductive.
[11] The film-shaped adhesive for semiconductors according to any one of [1] to [10], wherein the film-shaped adhesive for semiconductors is used for joining a semiconductor chip and a base body and for sealing a gap between the semiconductor chip and the base body.
[12] A method for producing the film-shaped adhesive for semiconductors according to any one of [1] to [11], the method comprising:
a step of providing a first adhesive layer and a second adhesive layer such that one of the adhesive layers is on top of the other,
wherein the first adhesive layer is a layer that includes the first epoxy resin, the first imidazole-based curing agent, and the (meth)acrylic compound but does not include a flux compound, and
the second adhesive layer is a layer including the second epoxy resin, the second imidazole-based curing agent, and the flux compound.
[13] An adhesive tape comprising:
the film-shaped adhesive for semiconductors according to any one of [1] to [11]; and
a backgrind tape provided on the film-shaped adhesive for semiconductors on the opposite side of the first adhesive region side as viewed from the second adhesive region.
[14] A method for producing a semiconductor device, the method comprising:
a step of preparing a film-shaped adhesive-attached semiconductor chip including a semiconductor chip and the film-shaped adhesive for semiconductors according to any one of [1] to [11], provided on the semiconductor chip such that a surface of the first adhesive region on the opposite side from the second adhesive region faces the semiconductor chip side; and
a step of disposing the film-shaped adhesive-attached semiconductor chip on a base body from the film-shaped adhesive side, and heating the assembly so as to electrically connect a connecting part of the semiconductor chip and a connecting part of the base body and to seal a gap between the semiconductor chip and the base body.
[15] A semiconductor device comprising:
a semiconductor chip including a first connecting part;
a base body including a second connecting part electrically connected to the first connecting part; and
a sealing part joining the semiconductor chip and the base body and filling a gap between the semiconductor chip and the base body,
wherein the sealing part is a cured product of the film-shaped adhesive for semiconductors according to any one of [1] to [11].

### Advantageous Effects of Invention

According to the present disclosure, a film-shaped adhesive for semiconductors that can suppress the amount of fillet generated while ensuring sufficient sealing properties, can be provided.

### BRIEF DESCRIPTION OF DRAWINGS

FIG. 1 is a schematic cross-sectional view illustrating one embodiment of a film-shaped adhesive for semiconductors of the present disclosure.

FIG. 2 (a) of FIG. 2 is a schematic cross-sectional view illustrating one embodiment of a semiconductor device of the present disclosure, and (b) of FIG. 2 is a schematic cross-sectional view illustrating another embodiment of the semiconductor device of the present disclosure.

FIG. 3 is a schematic cross-sectional view illustrating another embodiment of the semiconductor device of the present disclosure.

FIG. 4 is a process cross-sectional view schematically illustrating one embodiment of a method for producing a semiconductor device of the present disclosure.

FIG. 5 is a process cross-sectional view schematically illustrating a process subsequent to FIG. 4.

FIG. 6 is a process cross-sectional view schematically illustrating a process subsequent to FIG. 5.

FIG. 7 is a process cross-sectional view schematically illustrating a process subsequent to FIG. 6.

FIG. 8 is a process cross-sectional view schematically illustrating a process subsequent to FIG. 7.

### DESCRIPTION OF EMBODIMENTS

According to the present specification, the term “(meth)acryl” means at least one of acryl and methacryl corresponding thereto. The same also applies to other similar expressions such as “(meth)acryloyl” and “(meth)acrylate”. Furthermore, a numerical value range expressed by using the term “to” represents a range including the numerical values described before and after the term “to” as the minimum value and the maximum value, respectively. Furthermore, unless specifically stated otherwise, the units of the numerical values described before and after the term “to” are the same. With regard to a numerical value range described in the present specification, the upper limit value or the lower limit value of the numerical value range may be replaced with a value indicated in the Examples. Furthermore, upper limit values and lower limit values that are described individually can be combined arbitrarily. Unless particularly stated otherwise, the materials that will be mentioned below may be used singly, or two or more kinds thereof may be used in combination. In a case where there are a plurality of substances corresponding to each component in the composition, unless particularly stated otherwise, the content of each component in the composition means the total amount of the plurality of substances present in the composition.

Embodiments of the present disclosure will be described in detail below with reference to the drawings as needed. In the drawings, the same or equivalent parts will be assigned with the same reference numerals, and overlapping descriptions will not be repeated. Furthermore, unless particularly stated otherwise, the positional relationships such as upper, lower, right, and left are based on the positional relationships shown in the drawings. In addition, the dimensional ratios in the drawings are not limited to the ratios shown in the drawings.

### <Film-Shaped Adhesive for Semiconductors>

A film-shaped adhesive for semiconductors (hereinafter, simply referred to as “film-shaped adhesive”) of one embodiment is an adhesive used for connection (joining) and sealing of connecting members such as semiconductor chips, and can be used for joining a semiconductor chip and a base body and also for sealing a gap between a semiconductor chip and a base body.

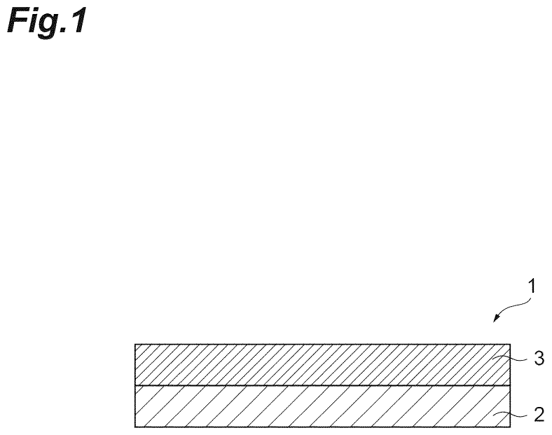

FIG. 1 is a schematic cross-sectional view showing a film-shaped adhesive according to one embodiment. The film-shaped adhesive 1 shown in the same drawing has a first adhesive region 2 not including a flux compound and a second adhesive region 3 including a flux compound, along the thickness direction (up-to-down direction in FIG. 1). The first adhesive region 2 includes an epoxy resin, an imidazole-based curing agent, and a (meth)acrylic compound, and the second adhesive region includes an epoxy resin, an imidazole-based curing agent, and the above-described flux compound. In the following description, the adhesive constituting the first adhesive region 2 is referred to as first adhesive, and the adhesive constituting the second adhesive region 3 is referred to as second adhesive. Furthermore, the epoxy resin and the imidazole-based curing agent included in the first adhesive are referred to as first epoxy resin and first imidazole-based curing agent, respectively, and the epoxy resin and the imidazole-based curing agent included in the second adhesive are referred to as second epoxy resin and second imidazole-based curing agent, respectively.

The first adhesive region 2 and the second adhesive region 3 have predetermined thicknesses and are extended, for example, as shown in FIG. 1, along the principal plane direction (left-to-right direction in FIG. 1) of the film-shaped adhesive 1. The first adhesive region 2 and the second adhesive region 3 may be layered. That is, the first adhesive region 2 and the second adhesive region 3 may be a first adhesive layer and a second adhesive layer, respectively. The boundary between the first adhesive region 2 and the second adhesive region 3 is not necessarily clear and may not be visually recognizable. In FIG. 1, the first adhesive region 2 and the second adhesive region 3 are adjacent to each other; however, there may be a region different from the first adhesive region 2 and the second adhesive region 3 (for example, a region including a mixture of the first adhesive and the second adhesive) between the first adhesive region 2 and the second adhesive region 3.

Incidentally, in recent years, along with higher functionalization and higher integration of packages, the gaps between layers and the pitches between wiring lines have become narrower, and therefore, the adhesive having fluidity at the time of connection easily overflows from the edges of connecting members (for example, semiconductor chips), so that overflowing parts called fillet are becoming more likely to be formed. Since such fillet may cause damage to the connecting members, there is a demand for the development of a technique for reducing the amount of fillet generated while ensuring sufficient sealing properties. In the case of simply using an adhesive having low fluidity in order to suppress fillet, the adhesive may not sufficiently fill in the space between the connecting parts of the connecting members and may cause defects such as voids, and therefore, it is difficult to solve the above-described problems by simply lowering the fluidity of the adhesive.

On the other hand, as a result of the investigation of the inventors of the present disclosure, it has been found that according to the above-described film-shaped adhesive, the generation of voids at the time of performing connection between connecting members and the generation of fillet due to excessive flow of the adhesive may be suppressed while ensuring sufficient sealing properties. The reason why such effect is provided is not clearly known; however, since the first adhesive region 2 and the second adhesive region 3 have the above-described specific compositions, it is speculated to be because the first adhesive region 2 has appropriate fluidity that is less likely to allow unfilled parts to occur, which cause the generation of voids at the time of sticking, while curing faster than the second adhesive region 3 at the time of connection, thus causing an excessive flow that causes the generation of fillet, and because the second adhesive region 3 flows more easily than the first adhesive region 2 and is less likely to allow unsealed parts to occur.

The thickness of the first adhesive region 2 (length in the thickness direction of the film-shaped adhesive 1) may be appropriately set in relation to the height of the connecting part in the connecting member to which the film-shaped adhesive 1 is stuck. When the height of the above-described connecting part is referred to as y1, and the thickness of the first adhesive region 2 is referred to as x1, from the viewpoint that intervention of a cured product of the first adhesive into the space between the connecting parts is less likely to occur, and the connection reliability can be further improved, it may be such that x1<y1, or it may be such that 1.0x1<y1≤1.5x1. Specifically, the thickness of the first adhesive region 2 may be 1 to 50 μm, or may be 3 to 50 μm, 4 to 30 μm, or 5 to 20 μm.

The thickness of the second adhesive region 3 may be 0.5 to 2 times the thickness of the first adhesive region 2, or may be 0.5 to 2.5 times, or 0.5 to 3 times the thickness of the first adhesive region 2. Specifically, the thickness of the second adhesive region 3 (length in the thickness direction of the film-shaped adhesive 1) may be 1 to 50 μm, or may be 3 to 50 μm, 4 to 30 μm, or 5 to 20 μm.

The thickness of the film-shaped adhesive 1 (for example, sum of the thickness of the first adhesive region 2 and the thickness of the second adhesive region 3) may be appropriately set in relation to the connecting parts of the connecting member. When the sum of heights of the connecting parts is referred to as x, and the total thickness of the film-shaped adhesive is referred to as y, from the viewpoint of the connectivity at the time of compression and the filling properties of the adhesive, it may be such that 0.70x≤y≤1.3x, or it may be such that 0.80x≤y≤1.2x. From the viewpoint that intervention of a cured product of the first adhesive into the space between the connecting parts is less likely to occur, and the connection reliability is even further improved, y>x may be satisfied. Specifically, the thickness of the film-shaped adhesive 1 may be 2 to 100 μm, or may be 6 to 100 μm, 8 to 60 μm, or 10 to 40 μm.

Hereinafter, the first adhesive constituting the first adhesive region 2, and the second adhesive constituting the second adhesive region 3 will be described.

### (First Adhesive)

The first adhesive includes a first epoxy resin, a first imidazole-based curing agent, and a (meth)acrylic compound but does not include a flux compound. Here, when it is said that the first adhesive does not include a flux compound, it means that the content of a flux compound in the first adhesive is equal to or less than the current detection limit (for example, 0.01% by mass or less based on the total amount of the first adhesive).

### [First Epoxy Resin]

The first epoxy resin is a compound having two or more epoxy groups in the molecule. Regarding the first epoxy resin, for example, a bisphenol A type epoxy resin, a bisphenol F type epoxy resin, a naphthalene type epoxy resin, a phenol novolac type epoxy resin, a cresol novolac type epoxy resin, a phenol aralkyl type epoxy resin, a biphenyl type epoxy resin, a triphenylmethane type epoxy resin, a triphenolmethane type epoxy resin, a dicyclopentadiene type epoxy resin, and various polyfunctional epoxy resins can be used. These can be used singly or as mixtures of two or more kinds thereof. Among these, when a triphenolmethane type epoxy resin (triphenolmethane skeleton-containing epoxy resin) is used, the amount of fillet generated tends to be further reduced.

Regarding the first epoxy resin, from the viewpoint of suppressing the epoxy resin from being decomposed to generate volatile components at the time of connection at a high temperature, an epoxy resin having a thermal weight loss rate of 5% or less at the temperature at the time of connection may be used. For example, in a case where the temperature at the time of connection is 250° C., an epoxy resin having a thermal weight loss rate at 250° C. of 5% or less may be used. Furthermore, for example, in a case where the temperature at the time of connection is 300° C., an epoxy resin having a thermal weight loss rate at 300° C. of 5% or less may be used.

Regarding the first epoxy resin, from the viewpoint that it is easy to suppress the occurrence of cracks and fissures on the film surface, an epoxy resin that is liquid at 25° C. (hereinafter, simply referred to as “liquid epoxy resin”) may also be used. Here, the phrase “liquid at 25° C.” means that the viscosity at 25° C. as measured with an E type viscometer is 400 Pas or less. Examples of the liquid epoxy resin include glycidyl ether of a bisphenol A type resin, glycidyl ether of a bisphenol AD type resin, glycidyl ether of a bisphenol S type resin, glycidyl ether of a bisphenol F type resin, glycidyl ether of a hydrogenated bisphenol A type resin, glycidyl ether of an ethylene oxide adduct bisphenol A type resin, glycidyl ether of a propylene oxide adduct bisphenol A type resin, glycidyl ether of a naphthalene resin, and a trifunctional or tetrafunctional glycidyl amine.

From the viewpoint that it is easy to suppress the occurrence of cracks and fissures on the film surface, the content of the liquid epoxy resin in the first adhesive may be 5% by mass or more, or may be 10% by mass or more or 20% by mass or more, based on the total amount of the first epoxy resin included in the first adhesive. From the viewpoint that it is easy to suppress excessive increase in the tackiness of the film and from the viewpoint that it is easy to suppress edge fusion, the content of the liquid epoxy resin may be 30% by mass or less, or may be 20% by mass or less or 10% by mass or less, based on the total amount of the first epoxy resin.

The epoxy equivalent of the first epoxy resin may be 100 to 3000 g/eq, or may be 100 to 2000 g/eq or 100 to 1500 g/eq. When the epoxy equivalent of the first epoxy resin is within the above-described range, the balance between reactivity and fluidity during heating is likely to improve.

From the viewpoint of allowing the generation of fillet to be easily suppressed, the content of the first epoxy resin in the first adhesive may be 25% by mass or more, or may be 30% by mass or more or 35% by mass or more, based on the total amount of the first adhesive. From the viewpoint that it is easy to obtain satisfactory sealing properties and from the viewpoint that the generation of voids is easily suppressed, the content of the first epoxy resin may be 50% by mass or less, or may be 45% by mass or less or 40% by mass or less, based on the total amount of the first adhesive.

The content of the first epoxy resin in the first adhesive may be set in relation to the content of the above-described (meth)acrylic compound. When the ratio of the content of the first epoxy resin with respect to the content of the (meth)acrylic compound in the first adhesive is 3 to 11 in terms of mass ratio, high connection reliability is likely to be obtained, and the amount of fillet generated tends to be further reduced. From the viewpoint that the amount of fillet generated is further reduced, the above-described ratio may be 5 or greater, 7 or greater, or 9 or greater, and in addition to the above-described effects, the ratio may be 10 or less from the viewpoint that satisfactory sealing properties are likely to be obtained, and from the viewpoint that the generation of voids is easily suppressed.

### [First Imidazole-Based Curing Agent]

Examples of the imidazole-based curing agent include 2-phenylimidazole, 2-phenyl-4-methylimidazole, 1-benzyl-2-methylimidazole, 1-benzyl-2-phenylimidazole, 1-cyanoethyl-2-undecylimidazole, 1-cyano-2-phenylimidazole, 1-cyanoethyl-2-undecylimidazole trimellitate 1-cyanoethyl-2-phenylimidazolium trimellitate, 2,4-diamino-6-[2′-methylimidazolyl-(1′)]-ethyl-s-triazine, 2,4-diamino-6-[2′-undecylimidazolyl-(1′)]-ethyl-s-triazine, 2,4-diamino-6-[2′-ethyl-4′-methylimidazolyl-(1′)]-ethyl-s-triazine, 2,4-diamino-6-[2′-methylimidazolyl-(1′)]-ethyl-s-triazine isocyanuric acid adduct, 2-phenylimidazole isocyanuric acid adduct, 2-phenyl-4,5-dihydroxymethylimidazole, 2-phenyl-4-methyl-5-hydroxymethylimidazole, and an adduct of an epoxy resin and an imidazole. Furthermore, latent curing agents in which these compounds are microencapsulated can also be used. These can be used singly or in combination of two or more kinds thereof. Among these, from the viewpoint that more satisfactory sealing properties are likely to be obtained, and from the viewpoint that the generation of voids is easily suppressed, a compound having a triazine ring may be used.

From the viewpoint that the curability at the time of heating is improved, the content of the first imidazole-based curing agent in the first adhesive may be 1 part by mass or more, or may be 2 parts by mass or more or 3 parts by mass or more, with respect to 100 parts by mass of the first epoxy resin included in the first adhesive. From the viewpoint that intervention of the first adhesive into the space between the connecting parts can be made more difficult to occur, the content of the first imidazole-based curing agent may be 10 parts by mass or less, or may be 7 parts by mass or less or 5 parts by mass or less, with respect to 100 parts by mass of the first epoxy resin.

### [(Meth)Acrylic Compound]

The (meth)acrylic compound is a compound having one or more (meth)acryloyl groups in the molecule. As the (meth)acrylic compound, for example, (meth)acrylic compounds containing a bisphenol A type, bisphenol F type, naphthalene type, phenol novolac type, cresol novolac type, phenol aralkyl type, biphenyl type, triphenylmethane type, dicyclopentadiene type, fluorene type, adamantane type, or isocyanuric acid type skeleton; and various polyfunctional (meth)acrylic compounds (excluding the (meth)acrylic compounds containing the above-described skeleton) can be used. Examples of the polyfunctional (meth)acrylic compounds include pentaerythritol tri(meth)acrylate, dipentaerythritol poly(meth)acrylates (dipentaerythritol penta(meth)acrylate, dipentaerythritol hexa(meth)acrylate, and the like), and trimethylolpropane di(meth)acrylate. Among these, when a polyfunctional (meth)acrylic compound is used, the effect of the present invention tends to be further improved, and when a dipentaerythritol poly(meth)acrylate is used, the effect of the present invention tends to be even further improved. The number of functional groups (number of (meth)acryloyl groups) of the polyfunctional (meth)acrylic compound may be 2 to 8, or may be 3 to 7 or 4 to 6.

The molecular weight of the (meth)acrylic compound is, for example, 400 to 2000. The molecular weight of the (meth)acrylic compound may be less than 2000, or may be 1000 or less. As the molecular weight of the (meth)acrylic compound is smaller, the reaction proceeds easily, and the curing reaction ratio is increased.

The (meth)acrylic compounds can be used singly or in combination of two or more kinds thereof.

From the viewpoint of further reducing the amount of fillet generated, the content of the (meth)acrylic compound in the first adhesive may be 1% by mass or more, or may be 3% by mass or more or 5% by mass or more, based on the total amount of the first adhesive. From the viewpoint of improving the sealing properties and from the viewpoint of suppressing the generation of voids, the content of the (meth)acrylic compound may be 10% by mass or less, or may be 7% by mass or less or 5% by mass or less, based on the total amount of the first adhesive. From these viewpoints, the content of the (meth)acrylic compound may be 1% to 10% by mass, or may be 3% to 7% by mass or 3% to 5% by mass, based on the total amount of the first adhesive.

### [Other Components]

The first adhesive may further contain components other than those described above (other components).

For example, the first adhesive may include a thermosetting resin (a compound that is cured by heat as a result of a reaction with a thermal curing agent) other than an epoxy resin. Examples of the thermosetting resin other than an epoxy resin include a phenol resin and an acrylic resin. When the first adhesive contains a thermosetting resin other than an epoxy resin, the content of the first epoxy resin in the first adhesive may be 80% by mass or more, or may be 90% by mass or more or 100% by mass, based on the total amount of the thermosetting resin included in the first adhesive.

Furthermore, for example, the first adhesive may include a thermal curing agent other than an imidazole-based curing agent. Examples of the thermal curing agent other than an imidazole-based curing agent include a phenol resin-based curing agent, an acid anhydride-based curing agent, an amine-based curing agent, and a phosphine-based curing agent. When the first adhesive contains a thermal curing agent other than an imidazole-based curing agent, from the viewpoint that curing can be allowed to proceed rapidly when heating is performed at a low temperature, and the connection reliability can be improved by the flux activity that suppresses generation of an oxide film at the connecting parts, the content of the first imidazole-based curing agent in the first adhesive may be 80% by mass or more, or may be 90% by mass or more or 100% by mass, based on the total amount of the thermal curing agent included in the first adhesive.

Furthermore, for example, the first adhesive may include a radically polymerizable compound (a compound capable of a radical polymerization reaction along with the generation of radicals due to heat, light, radiation, electrochemical action, or the like) other than a (meth)acrylic compound. Examples of the radically polymerizable compound other than a (meth)acrylic compound include a vinyl compound. When the first adhesive contains a radically polymerizable compound other than a (meth)acrylic compound, the content of the (meth)acrylic compound in the first adhesive may be 80% by mass or more, or may be 90% by mass or more or 100% by mass, based on the total amount of the radically polymerizable compound included in the first adhesive.

Furthermore, for example, the first adhesive may contain a thermoplastic resin. A thermoplastic resin contributes to the improvement of heat resistance and the improvement of film-forming properties. Examples of the thermoplastic resin include a phenoxy resin, a polyimide resin, a polyamide resin, a polycarbodiimide resin, a cyanate ester resin, an acrylic resin, a polyester resin, a polyethylene resin, a polyether sulfone resin, a polyether imide resin, a polyvinyl acetal resin, a urethane resin, and an acrylic rubber. Among these, from the viewpoint that excellent heat resistance and film-forming properties are easily obtained, the thermoplastic resin may be any of a phenoxy resin, a polyimide resin, an acrylic rubber, a cyanate ester resin, and a polycarbodiimide resin, and from the viewpoint that excellent heat resistance and film-forming properties are more easily obtained, the thermoplastic resin may be any of a phenoxy resin, a polyimide resin, and an acrylic rubber. These thermoplastic resins can be used singly or as a mixture or a copolymer of two or more kinds thereof.

The weight average molecular weight of the thermoplastic resin is, for example, 10000 or greater, and may be 20000 or more or 30000 or more. According to such a thermoplastic resin, the heat resistance and the film-forming properties of the first adhesive can be further improved. From the viewpoint that an effect of improving heat resistance is likely to be obtained, the weight average molecular weight of the thermoplastic resin may be 1000000 or less, or may be 500000 or less. Incidentally, the weight average molecular weight as used in the present specification means a weight average molecular weight obtained when measured using high performance liquid chromatography (manufactured by SHIMADZU CORPORATION, trade name: C-R4A) and calculated relative to polystyrene standards. For the measurement, for example, the following conditions can be used.
Detector: LV4000 UV Detector (manufactured by Hitachi, Ltd., trade name)
Pump: L6000 Pump (manufactured by Hitachi, Ltd., trade name) Column: Gelpack GL-S300MDT-5 (two in total) (manufactured by Hitachi Chemical Company, Ltd., trade name)
Eluent: THF/DMF=1/1 (volume ratio)+LiBr (0.03 mol/L)+H3PO4 (0.06 mol/L)
Flow rate: 1 mL/min

From the viewpoint of having excellent stickability of the film-shaped adhesive 1 to connecting members (for example, semiconductor chips), the glass transition temperature (Tg) of the thermoplastic resin may be 120° C. or lower, or may be 100° C. or lower or 85° C. or lower. The above-described Tg is a Tg obtained when measured using a DSC (manufactured by PerkinElmer Inc., trade name: DSC-7 type) under the conditions of a sample amount of 10 mg, a temperature increase rate of 10° C./min, and a measurement atmosphere of air.

From the viewpoint that the heat resistance and the film-forming properties of the first adhesive are likely to improve, the content of the thermoplastic resin in the first adhesive may be 5% by mass or more, or may be 7% by mass or more or 10% by mass or more, based on the total amount of the first adhesive. From the viewpoint that the generation of fillet is easily suppressed, the content of the thermoplastic resin may be 30% by mass or less, or may be 25% by mass or less or 20% by mass or less, based on the total amount of the first adhesive.

Furthermore, for example, the first adhesive may contain a filler (filler material). A filler is effective for controlling the viscosity of the first adhesive, the physical properties of a cured product of the first adhesive, and the like. Specifically, suppression of void generation at the time of connection, reduction of the coefficient of moisture absorption of a cured product of the first adhesive, and the like can be promoted by using a filler. The filler may be an inorganic filler (inorganic particles) or an organic filler (organic particles). Examples of the inorganic filler include insulating inorganic fillers such as glass, silica, alumina, titanium oxide, mica, and boron nitride. Among these, when at least one selected from the group consisting of silica, alumina, titanium oxide, and boron nitride is used, the above-described effects are easily obtained, and when at least one selected from the group consisting of silica, alumina, and boron nitride is used, the above-described effects are more easily obtained. Examples of the organic filler include a resin filler (resin particles). Examples of the resin filler include polyurethane and polyimide. According to a resin filler, flexibility at a high temperature such as 260° C. can be imparted. It is noted that an organic filler composed of a thermoplastic resin does not correspond to the above-described thermoplastic resin.

From the viewpoint of having more excellent insulation reliability, the filler may be insulative. The first adhesive does not have to contain a filler that includes a conductive material such as silver, solder, or carbon black (conductive filler).

The physical properties of the filler may be appropriately adjusted by a surface treatment. From the viewpoint that dispersibility or adhesive power is improved, the filler may be a filler that has been subjected to a surface treatment. Examples of the surface treatment agent include glycidyl-based (epoxy-based), amine-based, phenyl-based, phenylamino-based, (meth)acryl-based, and vinyl-based compounds.

The average particle size of the filler is, for example, 0.5 to 1.5 μm. The average particle size of the filler may be 1.5 μm or less from the viewpoint of preventing jamming at the time of flip-chip connection, and may be 1.0 μm or less from the viewpoint of having excellent visibility (transparency). The average particle size of the filler is the particle size at a point corresponding to 50% of the volume when a cumulative frequency distribution curve based on the particle size is determined by taking the total volume of the particles as 100%, and the average particle size can be measured with a particle size distribution analyzer using a laser diffraction scattering method, or the like.

From the viewpoint that deterioration of the heat dissipation properties is suppressed, and from the viewpoint that the generation of voids, an increase in the coefficient of moisture absorption, and the like are easily suppressed, the content of the filler in the first adhesive may be 25% by mass or more, or may be 30% by mass or more or 35% by mass or more, based on the total amount of the first adhesive. From the viewpoint of suppressing the occurrence of jamming (trapping) of the filler at the connecting parts, the content of the filler may be 60% by mass or less, or may be 55% by mass or less or 50% by mass or less, based on the total amount of the first adhesive.

In a case where the filler includes an inorganic filler and an organic filler, the content of the inorganic filler in the first adhesive may be 60% by mass or more, 70% by mass or more, or 80% by mass or more, may be 98% by mass or less, 95% by mass or less, or 90% by mass or less, and may be 60% to 98% by mass, 70% to 95% by mass, or 80% to 90% by mass, based on the total amount of the filler included in the first adhesive.

Furthermore, for example, the first adhesive may contain a radical polymerization initiator. The radical polymerization initiator may be a photoradical polymerization initiator, or may be a thermal radical polymerization initiator.

The photoradical polymerization initiator is a compound that is decomposed when irradiated with, for example, light including wavelengths in the range of 150 to 750 nm (for example, ultraviolet light) and generates free radicals, and examples thereof include photopolymerization initiators having structures such as an oxime ester structure, a bisimidazole structure, an acridine structure, an α-aminoalkylphenone structure, an aminobenzophenone structure, an N-phenylglycine structure, an acylphosphine oxide structure, a benzyl dimethyl ketal structure, an «-hydroxyalkylphenone structure, and an «-hydroxyacetophenone structure.

Examples of the thermal radical polymerization initiator include organic peroxides such as 1,1,3,3-tetramethylbutyl peroxyneodecanoate, di(4-t-butylcyclohexyl) peroxydicarbonate, di(2-ethylhexyl) peroxydicarbonate, cumyl peroxyneodecanoate, dilauroyl peroxide, 1-cyclohexyl-1-methylethyl peroxyneodecanoate, t-hexyl peroxyneodecanoate, t-butyl peroxyneodecanoate, t-butyl peroxypivalate, 1,1,3,3-tetramethylbutyl peroxy-2-ethylhexanoate, 2,5-dimethyl-2,5-di(2-ethylhexanoyl peroxy) hexane, t-hexyl peroxy-2-ethylhexanoate, t-butyl peroxy-2-ethylhexanoate, t-butyl peroxyneoheptanoate, t-amyl peroxy-2-ethylhexanoate, di-t-butyl peroxy hexahydroterephthalate, t-amyl peroxy-3,5,5-trimethylhexanoate, 3-hydroxy-1,1-dimethylbutyl peroxyneodecanoate, t-amyl peroxyneodecanoate, di(3-methylbenzoyl) peroxide, dibenzoyl peroxide, di(4-methylbenzoyl) peroxide, t-hexyl peroxy isopropyl monocarbonate, t-butyl peroxymaleic acid, t-butyl peroxy-3,5,5-trimethylhexanoate, t-butyl peroxylaurate, 2,5-dimethyl-2,5-di(3-methylbenzoyl peroxy) hexane, t-butyl peroxy-2-ethylhexyl monocarbonate, t-hexyl peroxybenzoate, 2,5-dimethyl-2,5-di(benzoyl peroxy) hexane, t-butyl peroxybenzoate, dibutyl peroxy trimethyl adipate, t-amyl peroxy normal octoate, t-amyl peroxy isononanoate, and t-amyl peroxybenzoate; and azo compounds such as 2,2′-azobis-2,4-dimethyl valeronitrile, 1,1′-azobis(1-acetoxy-1-phenylethane), 2,2′-azobisisobutyronitrile, 2,2′-azobis(2-methylbutyronitrile), 4,4′-azobis(4-cyanovaleric acid), and 1,1′-azobis(1-cyclohexanecarbonitrile).

From the viewpoint of further enhancing the effects of suppressing fillet, reducing voids, and improving the sealing properties, the content of the radical polymerization initiator in the first adhesive may be less than 0.1 parts by mass, or may be 0.01 parts by mass or less, with respect to 100 parts by mass of the (meth)acrylic compound included in the first adhesive. From the same viewpoints, the first adhesive does not have to include a radical polymerization initiator. Here, when it is said that the first adhesive does not include a radical polymerization initiator, it means that the content of the radical polymerization initiator in the first adhesive is equal to or less than the current detection limit (for example, 0.01% by mass or less based on the total amount of the first adhesive).

The first adhesive may further contain additives such as an antioxidant, a silane coupling agent, a titanium coupling agent, a leveling agent, and an ion trapping agent. These can be used singly or in combination of two or more kinds thereof. These contents may be appropriately adjusted such that the effect of each additive is exhibited.

### (Second Adhesive)

The second adhesive includes a second epoxy resin, a second imidazole-based curing agent, and a flux compound.

### [Second Epoxy Resin and Second Imidazole-Based Curing Agent]

For the second epoxy resin and the second imidazole-based thermal curing agent, the same ones as those mentioned as examples of the first epoxy resin and the first imidazole-based curing agent can be used, and preferred embodiments thereof are also the same. The first epoxy resin and the second epoxy resin may be the same or may be different. The first imidazole-based curing agent and the second imidazole-based curing agent may be the same or may be different.

From the viewpoint of allowing the generation of fillet to be easily suppressed, the content of the second epoxy resin in the second adhesive may be 25% by mass or more, or may be 30% by mass or more or 35% by mass or more, based on the total amount of the second adhesive. From the viewpoint that it is easy to obtain satisfactory sealing properties and adhesiveness, the content of the second epoxy resin may be 50% by mass or less, or may be 45% by mass or less or 40% by mass or less, based on the total amount of the second adhesive.

From the viewpoint that curability at the time of heating is improved, the content of the second imidazole-based curing agent in the second adhesive may be 1 part by mass or more, or may be 2 parts by mass or more or 3 parts by mass or more, with respect to 100 parts by mass of the second epoxy resin included in the second adhesive. From the viewpoint that intervention of the second adhesive into the space between the connecting parts can be made more difficult to occur, the content of the second imidazole-based curing agent may be 10 parts by mass or less, or may be 7 parts by mass or less or 5 parts by mass or less, with respect to 100 parts by mass of the second epoxy resin included in the second adhesive.

### [Flux Compound]

The flux compound is a compound having flux activity. As the flux compound, any known flux compound can be used without particular limitation as long as it reduces and removes an oxide film on the surface of solder or the like and facilitates metal joining. Regarding the flux compound, one kind thereof may be used alone, or two or more kinds thereof may be used in combination.

From the viewpoint of obtaining sufficient flux activity and obtaining more excellent connection reliability, the flux compound may be a compound having a carboxy group (carboxylic acid), or may be a polycarboxylic acid having two or more carboxy groups. Since a polycarboxylic acid is less likely to be volatilized at the high temperature at the time of connection as compared with a compound having one carboxy group (monocarboxylic acid), the generation of voids can be further suppressed by using a polycarboxylic acid. Furthermore, among the polycarboxylic acids, a polycarboxylic acid having two carboxy groups has an excellent effect of suppressing an increase in the viscosity of the film-shaped adhesive 1 during storage, during a connection operation, and the like, as compared with polycarboxylic acids having three or more carboxy groups.

The flux compound having a carboxy group may be a compound having a group represented by the following Formula (1).

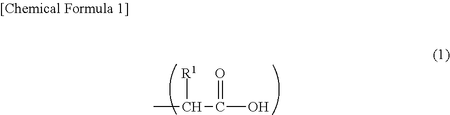

In Formula (1), R¹ represents a hydrogen atom or an electron-donating group.

From the viewpoint of having excellent reflow resistance and from the viewpoint of having more excellent connection reliability, R¹ may be electron-donating. In the present embodiment, the second adhesive may contain an epoxy resin and may further contain a compound in which R¹ is an electron-donating group among those compounds having a group represented by Formula (1). In this case, even for a flip-chip connection system, the production of a semiconductor device that is more excellent in terms of reflow resistance and connection reliability, is facilitated.

Examples of the electron-donating group include an alkyl group, a hydroxyl group, an amino group, an alkoxy group, and an alkylamino group. The electron-donating group may be a group that is less likely to react with other components (for example, an epoxy resin), and may be specifically an alkyl group, a hydroxyl group, or an alkoxy group.

The alkyl group may be linear or branched. The alkyl group may be an alkyl group having 1 to 10 carbon atoms, or may be an alkyl group having 1 to 5 carbon atoms. As the number of carbon atoms of the alkyl group is larger, the electron-donating properties and steric hindrance tend to increase. An alkyl group whose number of carbon atoms is in the above-described range is excellent in terms of the balance between electron-donating properties and steric hindrance.

The flux compound having two carboxy groups may be a compound represented by the following Formula (2). According to the compound represented by the following Formula (2), the reflow resistance and connection reliability of a semiconductor device can be further improved.

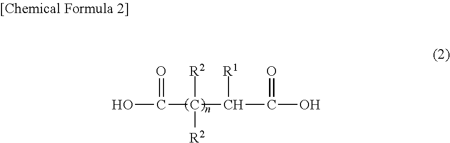

In Formula (2), R¹ has the same meaning as that in Formula (1). R² represents a hydrogen atom or an electron-donating group, and n represents an integer of 0 or 1 or greater.

The electron donatability represented by R² is the same as the examples of the above-mentioned electron-donating group described as R¹. R² may be the same as or different from R¹. A plurality of R² present in the compound may be identical with or different from each other.

n in Formula (2) may be 1 or greater. When n is 1 or greater, the flux compound is less likely to be volatilized even at the high temperature at the time of connection, and the generation of voids can be further suppressed, as compared with the case where n is 0. Furthermore, n in Formula (2) may be 15 or less, or may be 11 or less, 6 or less, or 4 or less. When n is 15 or less, more excellent connection reliability is obtained.

Specific examples of the flux compound such as described above include dicarboxylic acids such as succinic acid, glutaric acid, adipic acid, pimelic acid, suberic acid, azelaic acid, sebacic acid, undecanedioic acid, and dodecanedioic acid; and compounds obtained by substituting an electron-donating group at the 2-position of these dicarboxylic acids (for example, 2-methylglutaric acid). Among these, when 2-methylglutaric acid is used, effects such as suppression of fillet, reduction of voids, and improvement of sealing properties tend to be improved by the combination with an epoxy resin and an imidazole-based curing agent.

The melting point of the flux compound may be 150° C. or lower, or may be 140° C. or lower or 130° C. or lower. Such a flux compound is likely to sufficiently exhibit flux activity before a curing reaction between an epoxy resin and an imidazole-based curing agent occurs.

Accordingly, a semiconductor device having more excellent connection reliability can be obtained by using such a flux compound. The flux compound may be solid at room temperature (25° C.). The melting point of the flux compound may be 25° C. or higher, or may be 50° C. or higher. In the present specification, a melting point of 150° C. or lower means that the upper limit point of the melting point is 150° C. or lower, and a melting point of 25° C. or higher means that the lower limit point of the melting point is 25° C. or higher.

From the viewpoint that a flux effect is obtained more satisfactorily, the content of the flux compound in the second adhesive may be 0.1% by mass or more, or may be 0.3% by mass or more or 0.5% by mass or more, based on the total amount of the second adhesive. From the viewpoint of reducing the amount of warpage in the wafer at the time of producing a semiconductor device, the content of the flux compound may be 5% by mass or less, or may be 3% by mass or less or 2% by mass or less, based on the total amount of the second adhesive.

### [Other Components]

The second adhesive may include those components mentioned as examples of other components that can be included in the first adhesive. The thermoplastic resin in the first adhesive and the thermoplastic resin in the second adhesive may be the same or different. The same also applies to other components such as a filler.

From the viewpoint that the heat resistance and film-forming properties of the second adhesive are likely to improve, the content of the thermoplastic resin in the second adhesive may be 5% by mass or more, or may be 7% by mass or more or 10% by mass or more, based on the total amount of the second adhesive. From the viewpoint of allowing the occurrence of fillet to be easily suppressed, the content of the thermoplastic resin may be 30% by mass or less, or may be 25% by mass or less or 20% by mass or less, based on the total amount of the second adhesive.

From the viewpoint that deterioration of the heat dissipation properties is suppressed, and from the viewpoint that the generation of voids, an increase in the coefficient of moisture absorption, and the like are easily suppressed, the content of the filler in the second adhesive may be 25% by mass or more, or may be 30% by mass or more or 35% by mass or more, based on the total amount of the second adhesive. From the viewpoint of suppressing the occurrence of jamming (trapping) of the filler at the connecting parts, the content of the filler may be 60% by mass or less, or may be 55% by mass or less or 50% by mass or less, based on the total amount of the second adhesive.

The content of the radical polymerization initiator in the second adhesive may be 0.01 parts by mass or less based on the total amount of the second adhesive. The second adhesive does not have to include a radical polymerization initiator.

Since there are some flux compounds that react with radicals, and a curing reaction rapidly proceeds during heating due to the presence of a radically polymerizable compound and it is easy for a cured product to intervene into the space between the connecting parts, the second adhesive does not have to contain a radically polymerizable compound. The content of the radically polymerizable compound may be 0.5% by mass or less, or may be 0.05% by mass or less or 0% by mass, based on the total amount of the second adhesive.

The film-shaped adhesive 1 may be non-conductive. That is, the film-shaped adhesive 1 may be a so-called NCF (Non Conductive Film).

The film-shaped adhesive 1 described above may be provided in a state in which a base material such as a support film or a protective film is provided on the surface on the first adhesive region 2 side (opposite side of the second adhesive region 3), and/or the surface on the second adhesive region 3 side (opposite side of the first adhesive region 2). In the present disclosure, a laminated body including a base material and a film-shaped adhesive provided on the base material is referred to as an adhesive tape.

As the base material, a base material mentioned as an example of the base material used in the method for producing a film-shaped adhesive that will be described below can be used; however, the base material provided on the second adhesive region 3 side of the film-shaped adhesive 1 may be a backgrind tape. That is, another embodiment of the present disclosure is an adhesive tape including: the above-described film-shaped adhesive 1 and a backgrind tape provided on the film-shaped adhesive 1 on the opposite side of the first adhesive region 2 side as viewed from the second adhesive region 3 (backgrind tape-attached adhesive tape).

The backgrind tape is usually configured such that one principal surface side serves as a tacky adhesive layer; however, in this case, the backgrind tape is provided on the film-shaped adhesive 1 such that the surface on the tacky adhesive layer side comes on the film-shaped adhesive 1 side (for example, such that the tacky adhesive layer and the film-shaped adhesive are in contact). The thickness of the base material (for example, thickness of the backgrind tape) may be 20 to 300 μm.

The adhesive tape may be a laminated body of a base material and a film-shaped adhesive obtained by the method for producing a film-shaped adhesive that will be described below, that is, a method of applying a coating liquid on a base material, forming a coating film, and drying the coating film, or the adhesive tape may be a laminated body obtained by sticking a base material to the film-shaped adhesive 1 (for example, laminating the film-shaped adhesive 1 and a base material). In a case where the base material is a backgrind tape, when application and drying of a coating liquid are performed on the tacky adhesive layer of the backgrind tape, there is a possibility that problems such as breakage of the adhesive layer and migration of components between the tacky adhesive and the adhesive may occur, and therefore, an adhesive tape may be obtained by sticking a backgrind tape to the film-shaped adhesive 1.

### <Method for Producing Film-Shaped Adhesive for Semiconductors>

One embodiment of a method for producing the film-shaped adhesive 1 includes a step of preparing one of a first adhesive layer and a second adhesive layer on the other. Here, the first adhesive layer is a layer composed of the above-described first adhesive (that is, a layer that includes a first epoxy resin, a first imidazole-based curing agent, and a (meth)acrylic compound but does not include a flux compound) and forms the first adhesive region 2 in the film-shaped adhesive 1. The second adhesive layer is a layer composed of the above-described second adhesive (that is, a layer including a second epoxy resin, a second imidazole-based curing agent, and a flux compound) and forms the second adhesive region 3 in the film-shaped adhesive 1.

According to one embodiment, the above-described step may be, for example, a step of sticking together a first adhesive film including the above-described first adhesive layer, and a second adhesive film including the above-described second adhesive layer. In this embodiment, the method for producing the film-shaped adhesive 1 may further include a step of preparing the above-described first adhesive film and the above-described second adhesive film.

The step of preparing the first adhesive film may include forming the first adhesive layer on a base material (for example, a film-shaped base material). In the case of forming the first adhesive layer on a base material, for example, first, a first epoxy resin, a first imidazole-based curing agent, a (meth)acrylic compound, and other components (a filler, a thermoplastic resin, additives, and the like) that are added as necessary are added into an organic solvent, and the components are dissolved or dispersed by stirred mixing, kneading, and the like, to prepare a coating liquid including the first adhesive. Thereafter, the coating liquid is applied on a base material that has been subjected to a mold release treatment, by using a knife coater, a roll coater, an applicator, or the like to form a coating film, and then the amount of the organic solvent is reduced from the coating film by heating. As a result, a first adhesive layer can be formed on the base material.

Regarding the organic solvent used for preparing the coating liquid, an organic solvent having characteristics that can uniformly dissolve or disperse each component may be used. Examples of such an organic solvent include dimethylformamide, dimethylacetamide, N-methyl-2-pyrrolidone, dimethyl sulfoxide, diethylene glycol dimethyl ether, toluene, benzene, xylene, methyl ethyl ketone, tetrahydrofuran, ethyl cellosolve, ethyl cellosolve acetate, butyl cellosolve, dioxane, cyclohexanone, and ethyl acetate. These organic solvents can be used singly or in combination of two or more kinds thereof. Stirred mixing and kneading at the time of preparing the coating liquid can be performed, for example, using a stirrer, a Raikai mixer, a three-roll, a ball mill, a bead mill, or a Homo Disper.

The base material is not particularly limited as long as it has heat resistance that can withstand the heating conditions at the time of volatilizing the organic solvent, and examples thereof include polyolefin films such as a polypropylene film and a polymethylpentene film;

polyester films such as a polyethylene terephthalate film and a polyethylene naphthalate film; a polyimide film; and a polyetherimide film. The base material is not limited to a single-layered base material formed from any of these films, and may be a multilayer film formed from two or more kinds of materials. The base material may also be a film that has been subjected to a mold release treatment on the surface.

The drying conditions at the time of volatilizing the organic solvent from the coating film on the base material may be conditions in which the organic solvent is sufficiently volatilized. Specifically, heating may be performed, for example, under the conditions at 50 to 200° C. for 0.1 to 90 minutes. As long as the adjustment of voids or viscosity after mounting is not affected, the organic solvent may be removed to a level of 1.5% by mass or less with respect to the total amount of the first adhesive.

The step of preparing the second adhesive film may include forming the second adhesive layer on the base material. The second adhesive layer can be formed on the base material by a method similar to the method for forming the first adhesive layer, except that a second epoxy resin, a second imidazole-based curing agent, a flux compound, and other components that are added as needed (a filler, a thermoplastic resin, additives, and the like) are used.

Regarding the method of sticking the first adhesive film and the second adhesive film together, for example, methods of hot pressing, roll lamination, vacuum lamination, and the like may be mentioned. Lamination may be performed, for example, under heating conditions at 30 to 120° C.

The film-shaped adhesive 1 may be obtained by, for example, forming one of the first adhesive layer and the second adhesive layer on the base material and then forming the other one of the first adhesive layer and the second adhesive layer on the obtained first adhesive layer or second adhesive layer. The first adhesive layer and the second adhesive layer can be formed by the above-mentioned methods.

The film-shaped adhesive 1 may also be obtained by, for example, forming the first adhesive and the second adhesive on the base material substantially at the same time. Examples of a method for producing the first adhesive and the second adhesive by simultaneous coating include coating methods such as a sequential coating method and a multilayer coating method.

### <Semiconductor Device>

Next, a semiconductor device produced by using the film-shaped adhesive for semiconductors of the above-described embodiments will be described.

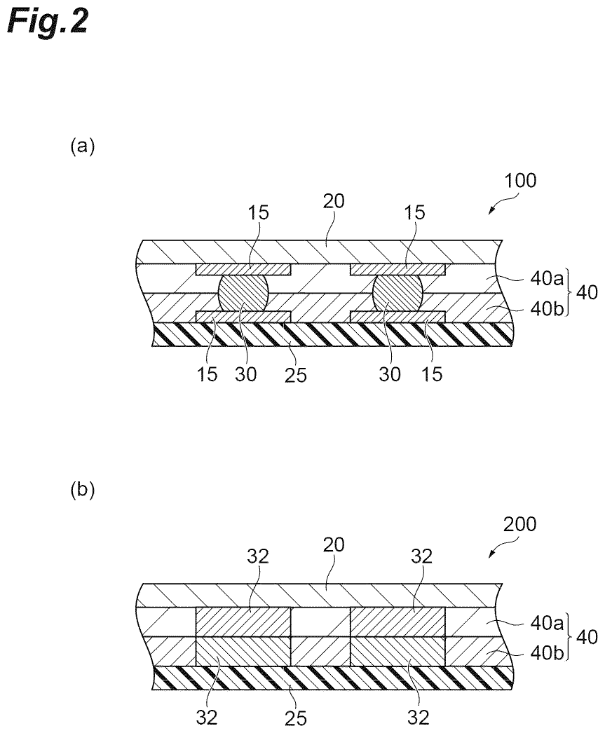

FIG. 2 is a schematic cross-sectional view illustrating one embodiment of the semiconductor device. A semiconductor device 100 shown in FIG. 2(a) includes: a semiconductor chip 20 and a base body 25 facing each other; wiring lines (first connecting part and second connecting part) 15 respectively disposed on surfaces of the semiconductor chip 20 and the base body 25, the surfaces facing each other; connecting bumps 30 connecting the wiring lines 15 of the semiconductor chip 20 and the base body 25 to each other; and a sealing part 40 formed of cured products of the adhesives (first adhesive and second adhesive) that fill the gap between the semiconductor chip 20 and the base body 25. The semiconductor chip 20 and the base body 25 are flip-chip connected by the wiring lines 15 and the connecting bumps 30. The wiring lines 15 and the connecting bumps 30 are sealed by cured products of the adhesives and are isolated from the external environment. The sealing part 40 has an upper portion 40a including a cured product of the first adhesive, and a lower portion 40b including a cured product of the second adhesive.

A semiconductor device 200 shown in FIG. 2(b) includes: a semiconductor chip 20 and a base body 25 facing each other; bumps (first connecting part and second connecting part) 32 respectively disposed on surfaces of the semiconductor chip 20 and the base body 25, the surfaces facing each other; and a sealing part 40 formed of cured products of the adhesives (first adhesive and second adhesive) that fill the gap between the semiconductor chip 20 and the base body 25. The semiconductor chip 20 and the base body 25 are flip-chip connected as the bumps 32 facing each other are connected to each other. The bumps 32 are sealed by cured products of the adhesives and are isolated from the external environment. The sealing part 40 has an upper portion 40a including a cured product of the first adhesive, and a lower portion 40b including a cured product of the second adhesive.

The semiconductor chip 20 is not particularly limited, and a semiconductor chip formed from an elemental semiconductor composed of the same type of element such as silicon or germanium, or a semiconductor chip formed from a compound semiconductor such as gallium arsenide or indium phosphide, can be used.

The base body 25 is not particularly limited as long as it is used for loading the semiconductor chip 20, and examples thereof include a semiconductor chip, a semiconductor wafer, and a wiring circuit board.

Examples of the semiconductor chip that can be used as the base body 25 are the same as the examples of the above-described semiconductor chip 20, and the same semiconductor chip as the semiconductor chip 20 may be used as the base body 25.

The semiconductor wafer that can be used as the base body 25 is not particularly limited, and a semiconductor wafer having a configuration in which a plurality of the semiconductor chips mentioned as examples of the above-described semiconductor chip 20 are linked together may be used.

The wiring circuit board that can be used as the base body 25 is not particularly limited, and a circuit board having wiring lines (wiring pattern) 15 formed on the surface of an insulating substrate containing glass epoxy, polyimide, polyester, ceramic, epoxy, bismaleimide triazine, or the like as a main component by removing unnecessary parts of a metal film by etching; a circuit board having wiring lines 15 formed on the surface of the above-described insulating substrate by metal plating or the like; a circuit board having wiring lines 15 formed on the surface of the above-described insulating substrate by printing a conductive substance; or the like can be used.

The connecting parts such as wiring lines 15 and bumps 32 contain gold, silver, copper, solder (main components are, for example, tin-silver, tin-lead, tin-bismuth, tin-copper, and tin-silver-copper), nickel, tin, lead, or the like as a main component, and may contain a plurality of metals.

Among the above-described metals, from the viewpoint of providing a package in which connecting parts have excellent electrical conductivity and thermal conductivity, gold, silver, and copper may be used. From the viewpoint of providing a package at reduced cost, silver, copper, and solder, which are inexpensive materials, may be used.

When an oxide film is formed on the surface of metal at room temperature, productivity may decrease while cost may increase, and therefore, from the viewpoint of suppressing the formation of an oxide film, gold, silver, copper, and solder may be used.

On the surface of the above-described wiring lines 15 and bumps 32, a metal layer containing gold, silver, copper, solder (main components are, for example, tin-silver, tin-lead, tin-bismuth, and tin-copper), tin, nickel, or the like as a main component, may be formed by, for example, plating. This metal layer may be composed only of a single component or may be composed of a plurality of components. Furthermore, the above-described metal layer may have a single layer structure or a structure in which a plurality of metal layers are laminated.

The semiconductor device may be such that a plurality of structures (packages) as shown in the semiconductor devices 100 and 200 are stacked. In this case, the semiconductor devices 100 and 200 may be electrically connected to each other by means of bumps, wiring lines, and the like, which include gold, silver, copper, solder (main components are, for example, tin-silver, tin-lead, tin-bismuth, tin-copper, and tin-silver-copper), tin, nickel, or the like.

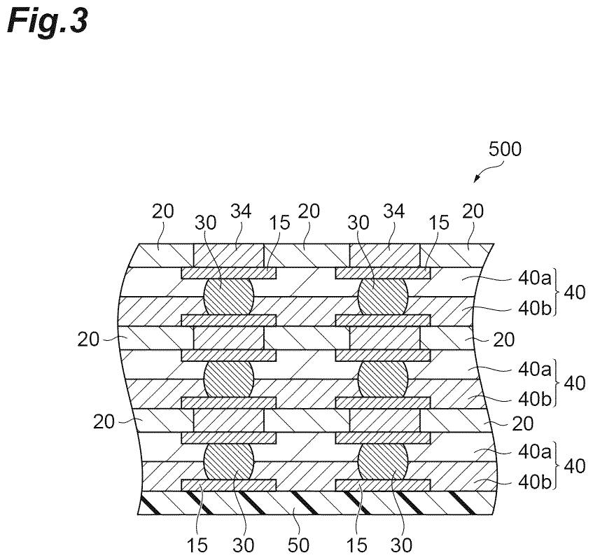

Regarding a technique of stacking a plurality of semiconductor devices, as shown in FIG. 3, for example, a TSV (Through-Silicon Via) technology may be mentioned. In a semiconductor device 500 shown in FIG. 3, as wiring lines 15 formed on an interposer 50 are connected to wiring lines 15 of a semiconductor chip 20 through connecting bumps 30, the semiconductor chip 20 and the interposer 50 are flip-chip connected. A gap between the semiconductor chip 20 and the interposer 50 is filled with cured products of adhesives (first adhesive and second adhesive), and the cured products constitute a sealing part 40. On the surface on the opposite side of the interposer 50 in the above-described semiconductor chip 20, semiconductor chips 20 are repeatedly stacked, with wiring lines 15, connecting bumps 30, and sealing parts 40 interposed therebetween. The wiring lines 15 of the patterned surfaces on the front and back sides of the semiconductor chip 20 are connected to each other by through electrodes 34 filling in the holes penetrating through the inside of the semiconductor chip 20. Regarding the material of the through electrode 34, copper, aluminum, and the like can be used.

It is made possible by such a TSV technology to acquire signals even from the back side of the semiconductor chip, which is normally not used. Furthermore, since the through electrodes 34 vertically pass through the semiconductor chips 20, the distance between semiconductor chips 20 facing each other, and the distance between a semiconductor chip 20 and an interposer 50 can be shortened, and flexible connection is enabled. The film-shaped adhesive for semiconductors of the present embodiment can be applied as a film-shaped adhesive for semiconductors between semiconductor chips 20 facing each other and between a semiconductor chip 20 and an interposer 50 in such a TSV technology.

Furthermore, in bump forming methods with a high degree of freedom, such as an area bump chip technology, semiconductor chips can be directly mounted as they are on a motherboard without using interposers. The film-shaped adhesive for semiconductors of the present embodiment can be applied even in a case where such semiconductor chips are mounted directly on a motherboard. The film-shaped adhesive for semiconductors of the present embodiment can also be applied when sealing gaps (voids) between substrates in a case where two wiring circuit boards are stacked.

### <Method for Producing Semiconductor Device>

Next, a method for producing a semiconductor device using the film-shaped adhesive for semiconductors of the above-described embodiments will be described.

The method for producing a semiconductor device according to one embodiment includes: for example, a step of preparing a film-shaped adhesive-attached semiconductor chip that includes a semiconductor chip and the film-shaped adhesive for semiconductors of the above-described embodiments provided on the semiconductor chip such that a surface of the first adhesive region on the opposite side from the second adhesive region faces the semiconductor chip side; and a step of disposing the film-shaped adhesive-attached semiconductor chip on a base body from the film-shaped adhesive side, and heating the assembly so as to electrically connect a connecting part of the semiconductor chip and a connecting part of the base body and to seal a gap between the semiconductor chip and the base body. The method for producing a semiconductor device may further include a step of sticking the film-shaped adhesive for semiconductors according to the above-described embodiments to a connecting surface of a semiconductor chip or a precursor thereof, with the first adhesive region side facing the connecting surface. Here, the precursor of a semiconductor chip means a member that is converted to a semiconductor chip by processing. A specific example of the precursor of a semiconductor chip is a semiconductor wafer. When a semiconductor wafer is used as the precursor of a semiconductor chip, the method for producing a semiconductor device may further include a step of dicing a semiconductor wafer or a film-shaped adhesive-attached semiconductor wafer.

In the method for producing a semiconductor device, the above-mentioned backgrind tape-attached adhesive tape may be used. In this case, the method for producing a semiconductor device may further include a lamination step of sticking the backgrind tape-attached adhesive tape to a connecting surface of a semiconductor wafer, which is a precursor of a semiconductor chip, with the film-shaped adhesive for semiconductors side facing the connecting surface; and a backgrinding step of grinding the semiconductor wafer to which the adhesive tape is stuck, from the opposite side of the adhesive tape.

In the following description, the method for producing a semiconductor device will be described by taking one embodiment of using a precursor of a semiconductor chip (semiconductor wafer) as an example.

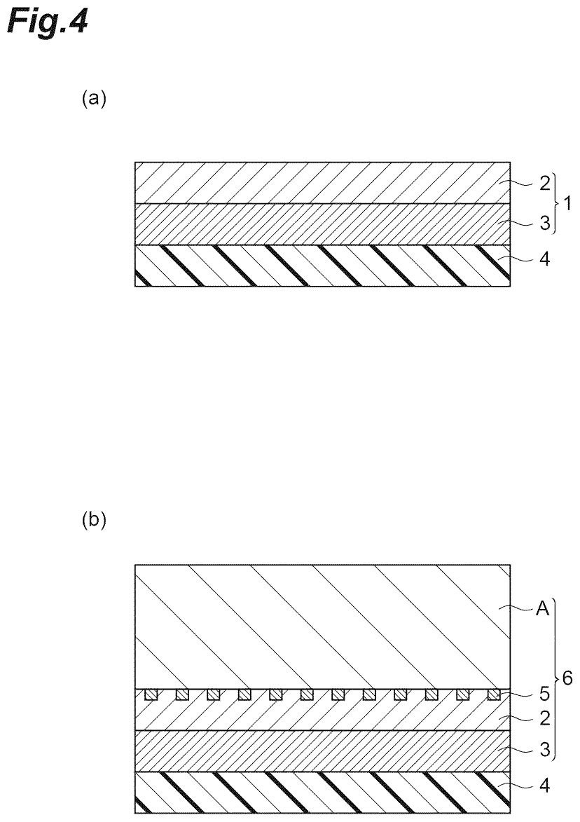

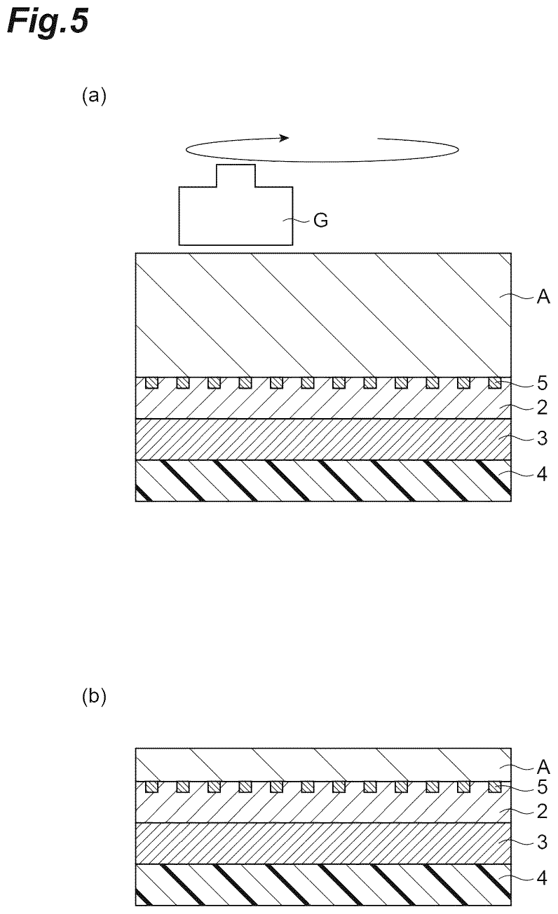

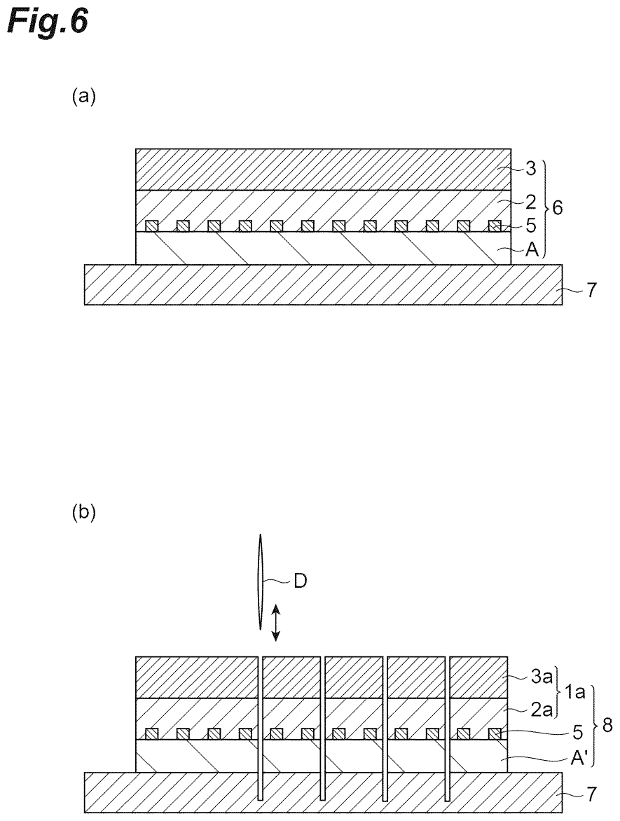

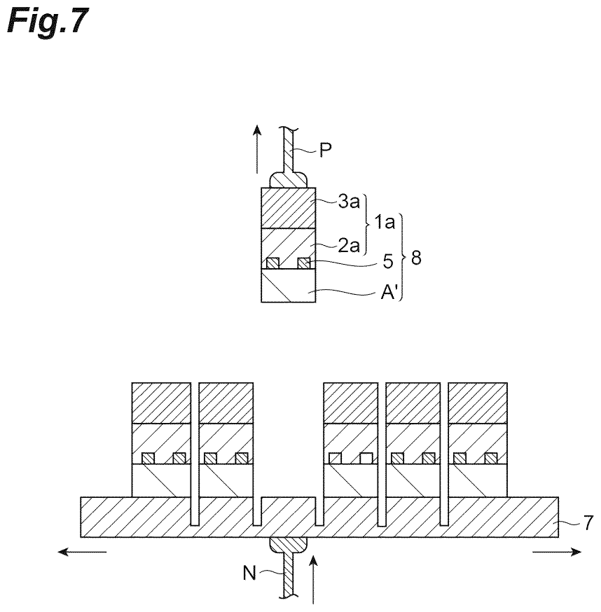

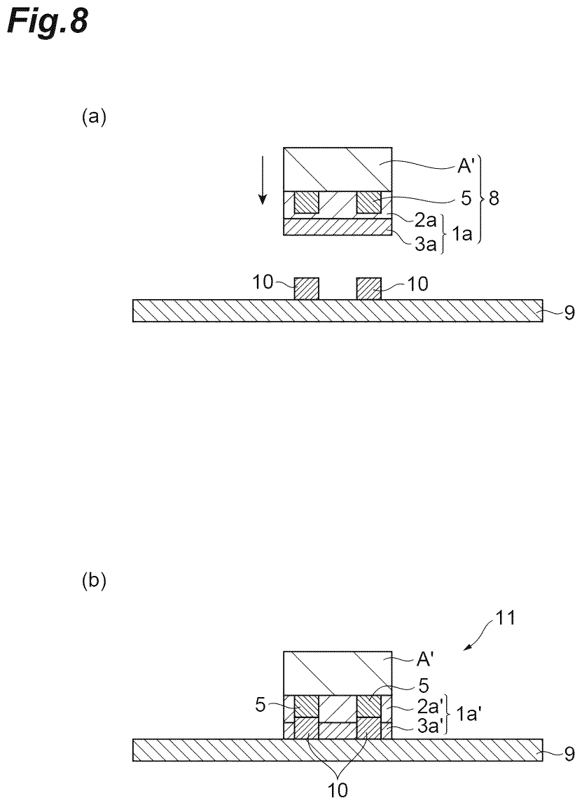

FIG. 4 to FIG. 8 are process cross-sectional views schematically showing one embodiment of the method for producing a semiconductor device. The production method according to one embodiment includes the following steps (a) to (e).
Step (a): A step of preparing a laminated body 6 including a semiconductor wafer A having a connecting part (first connecting part) 5 on one principal surface (connecting surface), and a film-shaped adhesive 1 provided on the principal surface of the semiconductor wafer A such that a face on the first adhesive region 2 side comes on the semiconductor wafer A side (see FIG. 4).
Step (b): A backgrinding step of grinding the side of the laminated body 6 opposite from the side where the film-shaped adhesive 1 is provided (opposite side from the side where the connecting part 5 of the semiconductor wafer A is provided) (see FIG. 5).
Step (c): A step of singulating the laminated body 6 and obtaining film-shaped adhesive-attached semiconductor chips 8 having connecting parts 5 (see FIG. 6).
Step (d): A step of picking up a film-shaped adhesive-attached semiconductor chip 8 from the singulated film-shaped adhesive 1a side (see FIG. 7).
Step (e): A step of disposing the film-shaped adhesive-attached semiconductor chip 8 on one principal surface of a base body 9 having a connecting part (second connecting part) 10 on the principal surface (connecting surface), with the film-shaped adhesive 1a side facing the principal surface, and heating the film-shaped adhesive-attached semiconductor chip 8 to electrically connect the connecting part 5 of the film-shaped adhesive-attached semiconductor chip 8 and the connecting part 10 of the base body 9, and to seal a gap between the semiconductor chip 8 and the base body 9 (see FIG. 8).

In a case where a semiconductor wafer whose thickness has been adjusted in advance is used, it is not necessary to carry out step (b).

### (Step (a))

Step (a) may be a step of preparing a laminated body 6 that has been produced in advance, or may be a step of producing a laminated body 6. The laminated body 6 may be produced by, for example, the following method.

First, an adhesive tape in which a base material 4 is provided on the second adhesive region 3 side of the film-shaped adhesive 1, is prepared, and this is placed on a predetermined apparatus (see FIG. 4(a)). The base material 4 is, for example, a backgrind tape. Next, a semiconductor wafer A having a connecting part 5 (wiring lines, bumps, and the like) on one principal surface is prepared, and the film-shaped adhesive 1 is stuck onto the principal surface (surface where the connecting part 5 is provided, connecting surface) of the semiconductor wafer A. As a result, a laminated body 6 in which the semiconductor wafer A, the first adhesive region 2, and the second adhesive region 3 are laminated in this order, is obtained (see FIG. 4(b)).

Sticking of the film-shaped adhesive 1 can be performed by hot pressing, roll lamination, vacuum lamination, or the like. The supply area and thickness of the film-shaped adhesive 1 are set as appropriate depending on the sizes of the semiconductor wafer and the base body, the height of the connecting part, and the like. In FIG. 4, the thickness of the film-shaped adhesive 1 is greater than the height of the connecting part 5 of the semiconductor wafer A, and the connecting part 5 is covered by the film-shaped adhesive 1; however, the thickness of the film-shaped adhesive 1 may be smaller than the height of the connecting part 5.

### (Step (b))

In step (b), for example, the semiconductor wafer A of the laminated body 6 is ground using a grinder G (see FIG. 5(a) and FIG. 5(b)). As a result, the semiconductor wafer A is thinned. The thickness of the semiconductor wafer after grinding may be, for example, 10 μm to 300 μm. From the viewpoints of size reduction and thickness reduction of semiconductor devices, the thickness of the semiconductor wafer may be 20 μm to 100 μm.

### (Step (c))

In step (c), for example, first, a dicing tape 7 is stuck to the semiconductor wafer A side of the laminated body 6, and this is placed on a predetermined apparatus (see FIG. 6(a)). The base material 4 may be peeled before sticking or after sticking of the laminated body 6 to the dicing tape 7. Next, the laminated body 6 is diced using a dicing saw D. In this way, the laminated body 6 is singulated, and a film-shaped adhesive-attached semiconductor chip 8 having a film-shaped adhesive 1a on a semiconductor chip A′ is obtained (see FIG. 6(b)). A connecting part 5 is provided on the surface on the film-shaped adhesive 1a side of the semiconductor chip A′. The film-shaped adhesive 1a has a first adhesive region (region formed from a first adhesive) 2a and a second adhesive region (region formed from a second adhesive) 3a.

### (Step (d))

In step (d), for example, while the film-shaped adhesive-attached semiconductor chips 8 obtained by the above-described dicing are separated apart from each other by expanding the dicing tape 7, the film-shaped adhesive-attached semiconductor chips 8 pushed up by a needle N from the dicing tape 7 side are picked up by a pick-up tool P from the film-shaped adhesive 1a side (see FIG. 7). A film-shaped adhesive-attached semiconductor chip 8 thus picked up is delivered to a bonding tool and used for bonding in step (e).

### (Step (e))

In step (e), for example, first, a base body 9 for loading semiconductor chips, which has a connecting part 10 (second connecting part) on one surface, is prepared, and alignment of the film-shaped adhesive-attached semiconductor chip 8 and the base body 9 is performed. Next, the film-shaped adhesive-attached semiconductor chip 8 is disposed on the principal surface of the base body 9 where the connecting part 10 (wiring lines, bumps, or the like) is provided, with the film-shaped adhesive 1a side facing the principal surface, by using a bonding tool, and the assembly is heated to thereby join the film-shaped adhesive-attached semiconductor chip 8 and the base body 9 (see FIG. 8(a) and FIG. 8(b)). As a result, the connecting part 5 of the film-shaped adhesive-attached semiconductor chip 8 and the connecting part 10 of the base body 9 are electrically connected, while at the same time, a sealing part 1a′ formed from a cured product of the film-shaped adhesive 1a is formed between the semiconductor chip A′ and the base body 9, a gap between the semiconductor chip 8 and the base body 9 is sealed, and a semiconductor device 11, which is a joined body of the film-shaped adhesive-attached semiconductor chip 8 and the base body 9, is obtained. The sealing part 1a′ has an upper portion 2a′ including a cured product of the first adhesive, and a lower portion 3a′ including a cured product of the second adhesive.

In a case where solder bumps are used for either the connecting part 5 or the connecting part 10 (for example, in a case where the connecting part 5 or the connecting part 10 is wiring lines provided with solder bumps), the connecting part 5 and the connecting part 10 are electrically and mechanically connected by solder joining.

Heating in the step (e) may be performed while disposing the semiconductor chip, or may be performed after the semiconductor chip is disposed. The heating and disposition in the step (e) may be thermocompression bonding. The step (e) may include a step of temporarily fixing after performing alignment (temporary fixing step), and a step of melting the bumps (for example, solder bumps) provided at the connecting parts by performing a heating treatment to join the semiconductor chip A′ and the base body 9 and to seal the connecting parts (sealing step). In the stage of temporary fixing, since it is not necessarily essential to form metal joining, the temporary fixing step can be carried out under a small load at a low temperature for a short time. Therefore, in a case where the temporary fixing step and the sealing step are carried out in the step (e), productivity can be improved, and at the same time, deterioration of the connecting parts can be suppressed.

The load to be applied for temporary fixing is set as appropriate in consideration of the control of the number of connecting parts (bumps), the absorption of height variations in the connecting parts (bumps), the amount of deformation of the connecting parts (bumps), and the like. As the load is larger, more voids are eliminated, making it easier to bring the connecting parts into contact. The load may be, for example, 0.009 N to 0.2 N per one connecting part (for example, a bump).

The heating in the sealing step may be carried out using an apparatus capable of heating to a temperature equal to or higher than the melting point of the metal of the connecting parts. The heating temperature may be a temperature at which curing of the film-shaped adhesive proceeds, or may be a temperature at which the film-shaped adhesive is completely cured. The heating temperature and the heating time are set as appropriate.

The heating time in the sealing step varies depending on the type of the metal constituting the connecting parts; however, as the heating time is shorter, productivity tends to improve. In a case where solder bumps are used for the connecting parts, the heating time may be 20 seconds or less, or may be 10 seconds or less or 5 seconds or less. In the case of metal connection of copper-copper or copper-gold, the connection time may be 60 seconds or less.

In the sealing step, pressurization may be performed together with heating by using an apparatus capable of heating and pressurization. That is, the heating in the sealing step may be heating by thermocompression bonding. In this case, the load (connection load) is set in consideration of the size of the connecting member, the number of the connecting parts, the variation in the height, the amount of deformation of the connecting parts by pressurization, and the like. The connection load may be, for example, greater than the atmospheric pressure and 1 MPa or less. As the connection load is larger, it is easier to suppress voids, and connectivity is easily improved. On the other hand, as the connection load is smaller, it is easier to suppress fillet. From these viewpoints, the load may be 0.05 to 0.5 MPa. The pressure-bonding time (connection time) may vary depending on the type of the metal constituting the connecting parts; however, as the pressure-bonding time is shorter, productivity tends to improve. In a case where the connecting parts are solder bumps, the pressure-bonding time may be 20 seconds or less, or may be 10 seconds or less or 5 seconds or less. In direct pressurization using a pressure-bonding machine, since it is difficult for the heat of the pressure-bonding machine to be transferred to fillet, from the viewpoint of easily applying sufficient effect to the fillet, pressurization may be performed by utilizing air pressure. Even from the viewpoints of batch sealing and suppression of fillet, the pressurization during heating may be performed by pressurization by air pressure (pressurization by a pressure reflow furnace, a pressure oven, or the like).

After the semiconductor chip A′ and the base body 9 are connected, a heating treatment may be performed using an oven or the like to further enhance the connection reliability.

### EXAMPLES

Hereinafter, the present disclosure will be described more specifically by way of Examples; however, the present disclosure is not intended to be limited to the Examples.

The details of the materials used in Examples and Comparative Examples are as follows.

### (Liquid Epoxy Resin)

YX7110B80: Flexible epoxy, manufactured by Mitsubishi Chemical Corporation, trade name “jERYX7110B80”, “jER” is a registered trademark (hereinafter, the same)
YL983U: Bisphenol F type liquid epoxy, manufactured by Mitsubishi Chemical Corporation, trade name “jERYL983U” (Solid epoxy resin)
EP1032: Triphenolmethane skeleton-containing polyfunctional solid epoxy, manufactured by Mitsubishi Chemical Corporation, trade name “jER1032H60”

### (Imidazole-Based Curing Agent)

2PHZ-PW: 2-Phenyl-4,5-dihydroxymethylimidazole, manufactured by SHIKOKU CHEMICALS CORPORATION, trade name
2MAOK-PW: 2,4-Diamino-6-[2′-methylimidazolyl-(1′)]-ethyl-s-triazine isocyanuric acid adduct, manufactured by SHIKOKU CHEMICALS CORPORATION, trade name

### (Phenoxy Resin)

ZX-1356-2: Phenoxy resin, manufactured by Tohto Kasei Co., Ltd., trade name, Tg=about 71° C., weight average molecular weight Mw=about 63000

### (Acrylic Compound)

A-DPH: Dipentaerythritol polyacrylate, manufactured by SHIN-NAKAMURA CHEMICAL Co., Ltd., trade name

### (Organic Filler)

EXL-2655: Core-shell type organic microparticles, manufactured by Rohm and Haas Japan KK, trade name (Silica filler)
KE180G-HLA: Silica filler, manufactured by ADMATECHS COMPANY LIMITED, trade name

### (Flux Compound)

2-Methylglutaric acid: Manufactured by Sigma-Aldrich Corporation, melting point=about 78° C.

### Examples 1 to 7 and Comparative Example 1

### (Production of First Adhesive Film)

The components shown in Table 1 were added to an organic solvent (methyl ethyl ketone) such that the NV value ([mass of coating material portion after drying]/[mass of coating material portion before drying]×100) would be 60%, and a mixed liquid was obtained. At this time, the amount of addition of each component was set to the amount (unit: parts by mass) shown in Table 1. Thereafter, beads having a diameter of φ1.0 mm and beads having a diameter of φ2.0 mm were added to the above-described mixed liquid, and the mixture was stirred for 30 minutes in a bead mill (Fritsch Japan Co., Ltd., planetary type fine grinding mill P-7). The amount of addition of the beads was the same mass as the non-volatile content (total amount of components other than the organic solvent) of the mixed liquid. After stirring, the beads were removed by filtration. In this way, coating liquids 1A to 8A for forming a first adhesive layer were obtained.

First adhesive films (first adhesive films 1A to 8A) including first adhesive layers 1A to 8A, respectively, were obtained by using the obtained coating liquids 1A to 8A. Specifically, first, a coating liquid was applied on a base material film (manufactured by Teijin Dupont Film Japan Limited, trade name “PUREX A54”) using a small-sized precision coating apparatus (Yasui Seiki, Inc.) such that the film thickness after drying would be 4.5 μm. Next, the coating film was dried (80° C./10 min) in a clean oven (manufactured by ESPEC CORP.) to obtain a first adhesive film including a first adhesive layer.

TABLE 1

| | | First adhesive layer | | | | | | | |
|---|---|---|---|---|---|---|---|---|---|
| | | 1A | 2A | 3A | 4A | 5A | 6A | 7A | 8A |
| Liquid epoxy resin | YX7110B80 | 2.3 | 2.4 | 2.4 | 2.4 | 2.5 | 2.6 | 2.7 | 2.7 |
| | YL983U | — | — | — | — | — | — | 3.1 | 3.1 |
| Solid epoxy resin | EP1032 | 27.7 | 28.9 | 28.9 | 28.9 | 29.7 | 31.4 | 29.9 | 33.5 |
| Imidazole-based | 2PHZ-PW | 1.4 | 1.4 | 1.4 | — | — | — | — | — |
| curing agent | 2MAOK-PW | — | — | — | 1.4 | 1.5 | 1.6 | 1.6 | 1.6 |
| Phenoxy resin | ZX-1356-2 | 13.8 | 14.4 | 14.4 | 14.4 | 14.8 | 15.7 | 16.5 | 16.5 |
| Acrylic compound | A-DPH | 10 | 7.8 | 7.8 | 7.8 | 6.4 | 3.4 | 3.6 | — |
| Organic filler | EXL-2655 | 4.6 | 4.8 | 4.8 | 4.8 | 4.9 | 5.2 | 5.5 | 5.5 |
| Silica filler | KE-180G-HLA | 40.1 | 40.1 | 40.1 | 40.1 | 40.1 | 40.1 | 37.0 | 37.0 |

| | | | | | |
|---|---|---|---|---|---|
| Epoxy resin:acrylic compound | 7.5:2.5 | 8:2 | 8.5:1.5 | 9.1:0.9 | 10:0 |

### (Production of Second Adhesive Film)

The components shown in Table 2 were added to an organic solvent (methyl ethyl ketone) such that the NV value would be 60%, and a mixed liquid was obtained. At this time, the amount of addition of each component was set to the amount (unit: parts by mass) shown in Table 2. Thereafter, beads having a diameter of φ1.0 mm and beads having a diameter of φ2.0 mm were added to the above-described mixed liquid, and the mixture was stirred for 30 minutes in a bead mill (Fritsch Japan Co., Ltd., planetary type fine grinding mill P-7). The amount of addition of the beads was the same mass as the non-volatile content (total amount of components other than the organic solvent) of the mixed liquid. After stirring, the beads were removed by filtration, and coating liquid 1B and coating liquid 2B for forming a second adhesive layer were obtained.

The obtained coating liquid 1B was applied on a base material film (manufactured by Teijin Dupont Film Japan Limited, trade name “PUREX A54”) using a small-sized precision coating apparatus (Yasui Seiki, Inc.) such that the film thickness after drying would be 4.5 μm. Next, the coating film was dried (80° C./10 min) in a clean oven (manufactured by ESPEC CORP.) to obtain a second adhesive film 1B including a second adhesive layer 1B. Furthermore, a second adhesive film 2B including a second adhesive layer 2B was obtained in the same manner, except that the coating liquid 2B was used instead of the coating liquid 1B.

TABLE 2

| | | Second adhesive layer | |
|---|---|---|---|
| | | 1B | 2B |
| Liquid epoxy resin | YX7110B80 | 6.3 | 2.9 |
| | YL983U | 2.8 | 3.3 |
| Solid epoxy resin | EP1032 | 29.9 | 34.3 |
| Imidazole-based | 2PHZ-PW | 1.1 | — |
| curing agent | 2MAOK-PW | — | 1.2 |
| Phenoxy resin | ZX-1356-2 | 13.9 | 14.4 |
| Organic filler | EXL-2655 | 5.6 | 5.8 |
| Silica filler | KE-180G-HLA | 39.4 | 37.0 |
| Flux compound | 2-Methylglutaric acid | 1.1 | 1.2 |

### (Production of Film-Shaped Adhesive)

A first adhesive layer and a second adhesive layer were stacked by laminating any one of the first adhesive films 1A to 8A produced as described above and the second adhesive film 1B or 2B in the combinations shown in Table 3, and film-shaped adhesives (total thickness 9.0 μm) of Examples 1 to 7 and Comparative Example 1 were produced. The lamination temperature was set to 50° C.

### Comparative Example 2

A second adhesive film 1B including a second adhesive layer 1B was obtained in the same manner as in the above-described section “Production of second adhesive film”, and then two layers of the obtained second adhesive layer 1B were stacked thereon to obtain a film-shaped adhesive (total thickness 9.0 μm) of Comparative Example 2.

### <Evaluation>

Connected structures (semiconductor devices) were produced by the following procedure, by using the film-shaped adhesives obtained in Examples 1 to 7 and Comparative Examples 1 and 2. Furthermore, evaluation of the fillet length, voids, and sealing properties was carried out by the methods described below, by using the obtained connected structures. The results are shown in Table 3.

### (Production of Connected Structure)

Each of the film-shaped adhesives obtained in Examples 1 to 7 and Comparative Examples 1 and 2 was cut out into a predetermined size (8 mm in length×8 mm in width×9.0 μm in thickness), and a sample for evaluation was produced. Next, the sample for evaluation was stuck to a surface of a solder bump-attached semiconductor chip (chip size: 7.3 mm in length×7.3 mm in width×0.15 mm in thickness, bump height: copper pillar+solder together was about 40 μm, number of bumps: 328), the surface being provided with the solder bumps (connecting surface), and a laminated body of the evaluation sample and the solder bump-attached semiconductor chip was obtained. At this time, in Examples 1 to 7 and Comparative Example 1, the evaluation sample was stuck to the solder bump-attached semiconductor chip, with the first adhesive layer side (opposite side of the second adhesive layer) facing the solder bump-attached semiconductor chip. Next, the above-described laminated body was mounted on a glass epoxy substrate (glass epoxy base material: 420 μm thick, copper wiring lines: 9 μm thick), with the evaluation sample side facing the glass epoxy substrate, using a flip mounting apparatus “FCB3” (manufactured by Panasonic Corporation, trade name). Mounting was performed under the conditions of setting the pressure-bonding head temperature to 350° C., the pressure-bonding time to 3 seconds, and the pressure-bonding pressure to 0.5 MPa. As a result, a connected structure (semiconductor device) in which a glass epoxy substrate and a solder bump-attached semiconductor chip were connected by daisy chain connection, was obtained.

### (Fillet Amount)

A connected structure obtained as described above was observed from the semiconductor chip side by using a digital microscope VHX-6000 (manufactured by KEYENCE CORPORATION), and the length of adhesive (fillet) overflowing from the four sides around the semiconductor chip was measured. Regarding the length of the fillet on each side, the maximum value of the shortest distances from the edges of the overflowing adhesive to the semiconductor chip was employed. The fillet amount was evaluated on the basis of the average value of the length of fillet measured at each of the four sides. When the average value was less than 100 μm, it was determined that the amount of fillet generated had been sufficiently reduced, and when the above-described average value was 100 μm or greater, it was determined that the fillet suppressing effect was insufficient.

### (Voids)

For a connected structure obtained as described above, images of the external appearance were taken using an ultrasonic diagnostic imaging apparatus (trade name “Insight-300”, manufactured by Insight k.k.), an image of the adhesive layer (layer formed from a cured product of the film-shaped adhesive for semiconductors) on the chip was captured using a scanner GT-9300UF (manufactured by Seiko Epson Corporation, trade name), void portions were identified by color tone correction and two-tone conversion using image processing software Adobe Photoshop (registered trademark), and a proportion occupied by the void portions was calculated using a histogram. When taking the area of the adhesive portion on the chip as 100%, a case in which the void generation ratio was 5% or less was rated as “A”, a case in which the void generation ratio was more than 5% and 10% or less was rated as “B”, and a case in which the void generation ratio was more than 10% was rated as “C”.

### (Sealing Properties)

A connected structure obtained as described above was observed from the semiconductor chip side by using a semiconductor/FPD inspection microscope MX63 (manufactured by Olympus Corporation), and the lengths of unfilled portions at the four corners of the chip were measured. Regarding the length of an unfilled portion, the maximum value of the shortest distances from the four corners of the chip to the filled site was employed. The sealing properties were rated as “A” when the length of the unfilled portion was less than 500 μm, and were rated as “B” when the length was 500 μm or greater.

TABLE 3

| | | Example | Example | Example | Example | Example | Example | Example | Comparative | Comparative |
|---|---|---|---|---|---|---|---|---|---|---|
| | | 1 | 2 | 3 | 4 | 5 | 6 | 7 | Example 1 | Example 2 |
| First adhesive | | 1A | 2A | 3A | 4A | 5A | 6A | 7A | 8A | — |
| Second adhesive | | 1B | 1B | 1B | 1B | 1B | 1B | 2B | 2B | — |
| Evaluation | Fillet | 57.7 | 90.7 | 80.8 | 69.7 | 74.6 | 83.5 | 92.2 | 126.3 | 143.9 |
| | amount | | | | | | | | | |
| | (μm) | | | | | | | | | |
| | Voids | A | A | A | A | A | A | A | A | C |
| | Sealing | A | A | A | A | A | A | A | A | A |
| | properties | | | | | | | | | |

### REFERENCE SIGNS LIST

1, 1a: film-shaped adhesive for semiconductors, 2, 2a: first adhesive region, 3, 3a: second adhesive region, 4: base material, 5: connecting part (first connecting part), 9: base body, 10: connecting part (first connecting part), 11: semiconductor device, 15: wiring line (first connecting part and second connecting part), 20: semiconductor chip, 25: base body, 30: connecting bump, 32: bump (first connecting part and second connecting part), 40: sealing part, 100, 200, 500: semiconductor device, A: semiconductor wafer, A′: semiconductor chip.

1. A film-shaped adhesive for semiconductors, comprising, along a thickness direction:
a first adhesive region not comprising a flux compound; and
a second adhesive region comprising a flux compound,
wherein the first adhesive region comprises a first epoxy resin, a first imidazole-based curing agent, and a (meth)acrylic compound, and
the second adhesive region comprises a second epoxy resin, a second imidazole-based curing agent, and the flux compound.

2. The film-shaped adhesive for semiconductors according to claim 1, wherein the first adhesive region does not comprise a radical polymerization initiator.

3. The film-shaped adhesive for semiconductors according to claim 1, wherein at least one of the first epoxy resin and the second epoxy resin comprises an epoxy resin that is liquid at 25° C.

4. The film-shaped adhesive for semiconductors according to claim 1, wherein at least one of the first epoxy resin and the second epoxy resin comprises a triphenolmethane type epoxy resin.

5. The film-shaped adhesive for semiconductors according to claim 1, wherein at least one of the first imidazole-based curing agent and the second imidazole-based curing agent comprises a triazine ring.

6. The film-shaped adhesive for semiconductors according to claim 1, wherein a ratio of a content of the first epoxy resin with respect to a content of the (meth)acrylic compound in the first adhesive region is 3 to 11 in terms of mass ratio.

7. The film-shaped adhesive for semiconductors according to claim 1, wherein the (meth)acrylic compound comprises a polyfunctional (meth)acrylic compound having two to eight (meth)acryloyl groups.

8. The film-shaped adhesive for semiconductors according to claim 1, wherein the flux compound comprises a polycarboxylic acid.

9. The film-shaped adhesive for semiconductors according to claim 1,
wherein a thickness of the first adhesive region is 1 to 50 μm, and
a thickness of the second adhesive region is 0.5 to 2 times the thickness of the first adhesive region.

10. The film-shaped adhesive for semiconductors according to claim 1, wherein the adhesive is electrically non-conductive.

11. The film-shaped adhesive for semiconductors according to claim 1, wherein the film-shaped adhesive for semiconductors is used for joining a semiconductor chip and a base body and for sealing a gap between the semiconductor chip and the base body.

12. A method for producing the film-shaped adhesive for semiconductors according to claim 1, the method comprising:
providing a first adhesive layer and a second adhesive layer such that one of the adhesive layers is on top of the other,
wherein the first adhesive layer is a layer that comprises the first epoxy resin, the first imidazole-based curing agent, and the (meth)acrylic compound but does not comprise a flux compound, and
the second adhesive layer is a layer comprising the second epoxy resin, the second imidazole-based curing agent, and the flux compound.

13. An adhesive tape comprising:
the film-shaped adhesive for semiconductors according to claim 1; and
a backgrind tape provided on the film-shaped adhesive for semiconductors on the opposite side of the first adhesive region side as viewed from the second adhesive region.

14. A method for producing a semiconductor device, the method comprising:
preparing a film-shaped adhesive-attached semiconductor chip comprising a semiconductor chip and the film-shaped adhesive for semiconductors according to claim 1, provided on the semiconductor chip such that a surface of the first adhesive region on the opposite side from the second adhesive region faces the semiconductor chip side; and
disposing the film-shaped adhesive-attached semiconductor chip on a base body from the film-shaped adhesive side, and heating the assembly so as to electrically connect a connecting part of the semiconductor chip and a connecting part of the base body and to seal a gap between the semiconductor chip and the base body.

15. A semiconductor device comprising:
a semiconductor chip comprising a first connecting part;
a base body comprising a second connecting part electrically connected to the first connecting part; and
a sealing part joining the semiconductor chip and the base body and filling a gap between the semiconductor chip and the base body,
wherein the sealing part is a cured product of the film-shaped adhesive for semiconductors according to claim 1.
